(19) United States
(12) Patent Application Publication
(10) Pub. No.: US 2016/0284265 A1
(43) Pub. Date: Sep. 29, 2016

(54) Method of Implementing Global Illumination With OLED Displays

(71) Applicant: eMagin Corporation, Hopewell Junction, NY (US)

(72) Inventor: Olivier Prache, Pleasantville, NY (US)

(21) Appl. No.: 15/082,869

(22) Filed: Mar. 28, 2016

Related U.S. Application Data
(60) Provisional application No. 62/138,679, filed on Mar. 26, 2015.

(51) Int. Cl. G09G 3/3208; G02F 1/141

(52) U.S. Cl. CPC G09G 3/3208; G02F 1/141; G09G 2320/10

(57) ABSTRACT

A method of implementing global illumination in an organic light emitting diode (OLED) display device utilizing an external shutter to reduce visual artifacts and motion blurring. The display device has a screen for displaying image data and a plurality of pixels each including an organic light-emitting diode. The method includes controlling emission of light from each light emitting diode along a path from the pixel to the screen. The shutter is coupled to the display device and has an on-time state, permitting light to pass therethrough, and an off-time state, blocking light from passing therethrough. The method includes loading image data into the plurality of pixels in raster scan order while the shutter is in the off-time state. The shutter is then switched to the on-time state to simultaneously allow emission of light from each pixel to pass therethrough. During the brief on-time state, image data is simultaneously displayed on the screen for the plurality of pixels thereby displaying the full image all at once.

### CROSS-REFERENCE TO RELATED APPLICATION

This application claims priority to provisional patent application Ser. No. 62/138,679 filed in the United States Patent and Trademark Office on Mar. 26, 2015, the entire disclosure and drawings of which are incorporated in their entirety by reference herein.

### FIELD OF THE INVENTION

The present invention relates to an electronic display device and operation method thereof, and more particularly, to a method for implementing global illumination with an organic light emitting diode (OLED) display or microdisplay utilizing an external shutter to reduce visual artifacts and motion blurring in high speed video applications and head-mounted cockpit displays.

### BACKGROUND OF THE INVENTION

In conventional displays, pixel data is scanned into the displays in a time sequential pattern because the video source transmits pixel data in a stream. It has been discovered for certain applications that it is unfavorable for these changes to be visible over time. Specifically, fast moving objects on an electronic display exhibit visual artifacts and motion blurring due to persistence of the image from the previous frame. This can occur within a scene or due to background change. Rolling shutter techniques have been used to partially compensate the effect when an object is moving at a high rate within a relatively fixed non-moving background. However, in situations where the background is also moving at a fast rate, for example, high speed video applications, video games, head-mounted cockpit displays, and the like, visual artifacts and motion blur are still perceived and distracting to the user.

For such applications, it has been discovered that the best technique is to utilize global illumination (also known as low persistence, global shutter design, global shutter technique, or global display). In contrast to rolling shutter techniques, in a global shutter technique all pixels integrate light simultaneously. For high-speed video applications, a global shutter technique minimizes the motion distortion otherwise formed by rolling shutter techniques. In particular, the global shutter technique scans the full frame until all pixel data has been loaded, and then enable all pixels in the active array to illuminate simultaneously for a short fraction of the frame time. Thereby allowing the human eye response to relax in between frames, which provides the perception of a smooth continuous motion.

However, because a display device implementing a global illumination technique will only turn on for a portion of the frame time, the brightness of the display device is affected. Adjustments are therefore required in order to maintain the same average brightness as a conventional raster-scanned display. It has been found that the brightness during the on-time must be inversely proportional to the ratio of on-time to frame time. However, this leads to significantly higher peak operating current, requiring not only adequate power routing in the display but also bias levels that allow this peak brightness to be reached. The power constraint leads to larger silicon die sizes, which not only drives the cost but also impacts the total system design. The bias level constraint leads to having to operate at a higher voltage bias, which may not be available at the technology node being considered for the design. In addition, limitations within the display technology including transparent electrode impedance and display array total capacitance, impact the effective and consistent control of the on-time parameter.

The present invention aims at circumventing these constraints by providing a display device having an external shutter. According to various embodiments of the invention, organic light emitting diode (OLED) displays are one type of popular display device that may be so adapted. As used herein, “OLED” refers to the underlying screen of a display device, for example, active (or passive) matrix OLED. It should be understood, however, that various embodiments of the present disclosure may be implemented on other types of transmissive or emissive displays, including, but not limited to, Organic Light Emitting Diode (OLED), LCD, devices incorporating certain microelectromechanical systems (MEMS), plasma display panels (PDP), and the like.

It is, therefore, a primary object of the present invention to provide a method for implementing global illumination with a display device utilizing an external shutter to reduce visual artifacts and motion blurring in high speed video applications and head-mounted cockpit displays.

It is another object of the present invention to provide a display device having an external shutter used with a conventional raster-scanned display to provide the capability of global illumination.

It is another object of the present invention to provide a method for implementing global illumination using a conventional raster-scanned display without placing power or bias constraints on the display device.

It is another object of the present invention to provide a method for implementing global illumination with a conventional active or passive matrix OLED display device having an electro-mechanical light shutter.

It is another object of the present invention to provide a method for implementing global illumination with a conventional active or passive matrix OLED display device having an electro-optical light shutter, which may include a liquid crystal light valve.

### SUMMARY OF THE INVENTION

The present invention cures some of the deficiencies in the prior art by providing a method for implementing global illumination with a display device utilizing an external shutter to reduce visual artifacts and motion blurring in high speed video applications and head-mounted cockpit displays.

In an illustrative embodiment of the present invention, a method of controlling emission of light in a display device which receives image data from a video source is provided. The display device has a screen and comprises a plurality of pixels each including a light emitting element configured to emit light along a path from the pixel to the screen. The method steps include providing a shutter disposed on the display device and operated to block emission of light from all pixels during a first portion video frame. The steps then include loading image data into each one of the plurality of pixels and controlling the light emitting element of each pixel based on the image data received during the first portion video frame. Lastly, the steps include simultaneously enabling emission of light from each pixel through the shutter during a second portion video frame. The light-emitting element may comprise an organic light emitting diode. The shutter may be a mechanical light shutter or an electro-optical light shutter. The electro-optical light shutter may be a liquid crystal light valve, which may further include a ferroelectric liquid crystal light valve. The shutter includes an off-time state during the first portion video frame and an on-time state during the second portion video frame. The on-time state of the shutter is transparent or open, while the off-time state of the shutter is non-transparent or closed. The display may be a microdisplay. The display may be active matrix or passive matrix. The image data loaded into the pixels may be in raster scan order. The first and second portion video frames together comprise a frame. The frame may be 1/60 of a second.

In an alternate embodiment of the present invention, a method of operating a display system in communication with a video source for receiving image data is provided. The method steps include providing a display device having a screen for displaying image data, the display device having a plurality of pixels each including a light-emitting diode. The method includes emitting light from each light emitting diode along a path from the pixel to the screen, and providing a shutter coupled to the display device having an on-time state and an off-time state, wherein the on-time state allows transmission of light to pass therethrough and the off-time state blocks transmission of light from passing therethrough. The method includes loading image data into the plurality of pixels in raster scan order until the image is loaded. Then, switching the shutter to simultaneously allow emission of light from each pixel to pass through the shutter. The full image is then displayed by simultaneously displaying image data for each of the plurality of pixels. The plurality of pixels may comprise active-matrix organic light-emitting diodes. The shutter may be a mechanical light shutter or an electro-optical light shutter. The electro-optical light shutter may be a liquid crystal light valve. The liquid crystal light valve may be a ferroelectric liquid crystal light valve.

These advantages of the present invention will be apparent from the following disclosure and the appended claims.

### BRIEF DESCRIPTION OF THE DRAWINGS

FIG. 1 is a schematic diagram of a display system in accordance with an illustrative embodiment of the present invention.

FIG. 2A is a side elevation view of a light emitting panel in a display device in accordance with an illustrative embodiment of the present invention.

FIG. 2B is a plan view of a base plate having a plurality of light emitting elements mounted thereon in accordance with an illustrative embodiment of the present invention.

FIG. 3 is a portion of an idealized AMOLED microdisplay having an active matrix of OLED pixels generating light through an external shutter to a display screen in accordance with an alternate embodiment of the present invention.

FIG. 4 is a cross-sectional view of a liquid crystal light valve of the display device in accordance with an alternate embodiment of the present invention.

FIG. 5 is a timing diagram of the operation of the shutter in accordance with an illustrative embodiment of the present invention.

FIG. 6 is a schematic diagram of the timing scheme of the display device in accordance with an illustrative embodiment of the present invention.

### DETAILED DESCRIPTION

The present invention is method for implementing global illumination with a display device to reduce visual artifacts and motion blurring in high speed video applications and head-mounted cockpit displays. It should be noted that the display devices described in the various embodiments of the invention are for illustrative purposes and the present invention is not limited to the specific devices described herein.

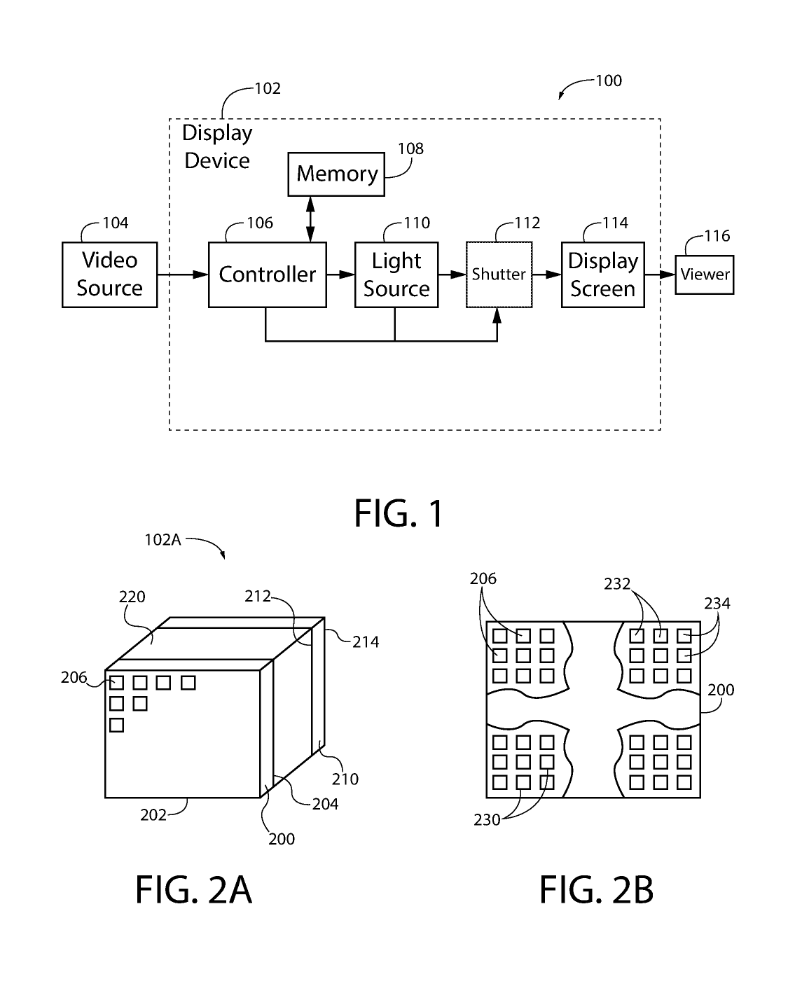

FIG. 1 illustrates a display system 100 according to an illustrative embodiment of the present invention, which includes a display device 102 in communication with a video source 104 for providing images to be displayed by the display device. The display device 102 is based on a conventional raster-scanned display. In its broadest context, the display device 102 includes a controller 106 coupled to a light source 110 for emanating light to a display screen 114. The display screen 114 includes a plurality of picture elements (i.e. pixels) each adapted to display a portion of an image underlying the display screen 114, such that the image is viewed by a user 116 on the display screen 114. The light source 110 provides light through an external shutter 112 for controlling the passage of light to the display screen 114. The controller 106 may control both the light source 110 and shutter 112. A memory 108 may be in communication with the controller 106 for receiving and storing image data from the video source 104 and sending image data to the controller 106. The controller 106 is adapted to control the rate at which data is accessed from the memory 108, thus avoiding frame latency.

According to an illustrative embodiment of the present, the controller 106 receives a signal from the video source 104. The video signal may include 2D and/or 3D image or video data and frame synchronization information (i.e. frame data). The controller 106 uses the video signal to update each of the picture elements (i.e. pixels) of the display screen 114. The controller 106 uses the synchronization information to synchronize the illumination provided by the light source 110 to provide an update scan of the display screen 114, preferably by loading frame data using conventional line at a time techniques (i.e. raster scanning technology). The controller 106 uses the synchronization information to synchronize the operation of the shutter 112, such that once the display screen 114 has been fully scanned, the shutter 112 is turned on for a predetermined amount of time, allowing the light of pixels to emanated therethrough and present the full field image on the display screen 114 at once rather than on a line at a time basis.

The shutter 112 used herein is an external shutter, which can be an electro-optical light shutter or an electro-mechanical light shutter. The shutter 112 has a transparent or on-time state allowing light to pass therethrough, and a non-transparent or off-time state blocking passage of light therethrough. The electro-optical light shutter is configured as a liquid crystal light valve, a ferroelectric light valve, or other array controlled light valve that is broken into elements. The ferroelectric light valve is optically bonded to the display device in such a manner as to minimize coupling and resolution losses. It should be understood by those skilled in the art that several techniques can be used to achieve this, such as for example, replacing the top cover glass of the display device with the light valve or by using an intermediate fiberoptic faceplate as a coupling element. The electro-mechanical shutter 112b is equivalent to that of a high-speed camera shutter. It should be understood, however, that various embodiments of the present disclosure may be implemented with other types of shutters known to those skilled in the art.

FIG. 2A illustrates display device 102A according to an illustrative embodiment of the present invention. The display device 102A includes a transparent base panel 200 and an electro-optical shutter 210 disposed on the base panel 200. The base panel 200 includes an outer surface 202 opposite an inner surface 204. The base panel 200 includes a plurality of light emitting elements or pixels 206 which generate an image on the display screen. Preferably, the pixels include active-matrix organic light-emitting diodes. When the base panel 200 is shuttered or blocked by the electro-optical light shutter 210, the image data being loaded into the pixels is obscured from view.

According to an illustrative embodiment, the electro-optical light shutter 210 is a voltage controlled light valve 210. The light valve 210 has an inner surface 212 opposite an outer surface 214. In the exemplary embodiment, an adhesive layer 220 is disposed between the transparent base panel 200 and the light valve 210, such that the inner surface 212 of the light valve 210 is adhered to the inner surface 204 of the base panel 200. The adhesive layer 220 may be an intermediate fiber-optic faceplate. In other embodiments, the inner surface 212 of the light valve 210 may be disposed directly onto the inner surface 204 of the base panel 200.

FIG. 2B illustrates a plan view of the base plate 200 according to an illustrative embodiment of the present invention. The light emitting elements 206 on the base plate 200 may include one or more light emitting diodes 230 (LEDs), such as organic LEDs (OLEDs), red-green-blue (RGB) LEDs, white phosphor based LEDs, or other electronic light sources. The LEDs 230 are mounted to the transparent base panel 200 and arranged in a plurality of columns 232 and rows 234. It should be understood that alternative LED arrangements and patterns are possible. It should also be understood that the light source may be arranged in an indirect, edge-lit configuration, where the LEDs may be positioned above, below, to the side of, or behind the display screen 114 with respect to the viewer of the light emanating from system 100, or that the light source may include a plurality of LEDs arranged in a direct back-lit configuration and configured to illuminate different portions of the display screen.

According to the illustrative embodiment, a printed circuit board (not shown) is connected to the base panel 200 for enabling the wiring of the light emitting elements 206 to a power source. The light emitting elements 206 are electrically coupled to drive circuitry (not shown) which provides the necessary electric current to the light emitting elements 206. It will be clear to those skilled in the art how to make and use the printed circuit board, it will also be clear to those skilled in the art that alternative power configurations are possible.

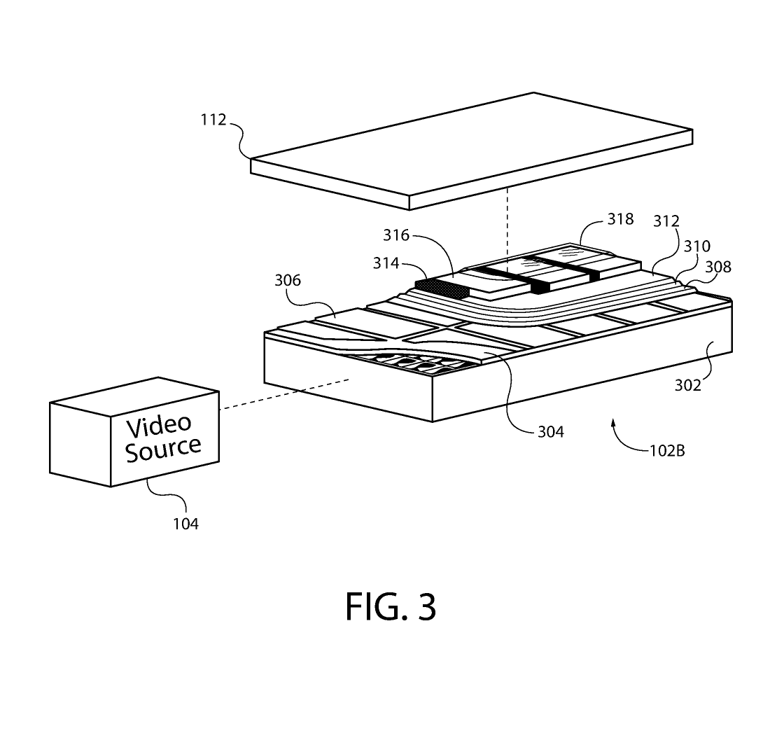

FIG. 3 illustrates display device 102B according to an alternate embodiment of the present invention. The device 102B is an idealized structure of an active matrix organic light emitting diode (AMOLED) microdisplay fabricated onto circuitry that controls and processes the video signal from the video source 104. The shutter 112, preferably a liquid crystal light valve, is coupled to the AMOLED microdisplay 102B. The device 102B uses an organic compound to produce the light when power is applied, and because the OLEDs produce their own light, there is no need for additional back-lighting as with LCD systems.

The device 102B includes a single crystal silicon substrate layer with integrated active matrix drives 302, a polarized insular layer with vias 304 above the substrate layer, and individual anode electrodes 306 for each color subpixel positioned above the insular layer 304. A white light emitting OLED layer 308 is deposited onto the anode layer 306, followed by a cathode layer 310 deposited on the OLED layer 308. One or more transparent seal layers 312 cover the cathode layer 310. The black matrix stripes 314, and color filter strips 316 (red, green, blue), are deposited onto the seal layers 312 and covered by a transparent protective layer or antireflective layer 318. The liquid crystal light valve 112 is coupled to the device 102B either by replacing the transparent protective layer 318 or by using an intermediate fiberoptic faceplate (not shown) as a coupling element.

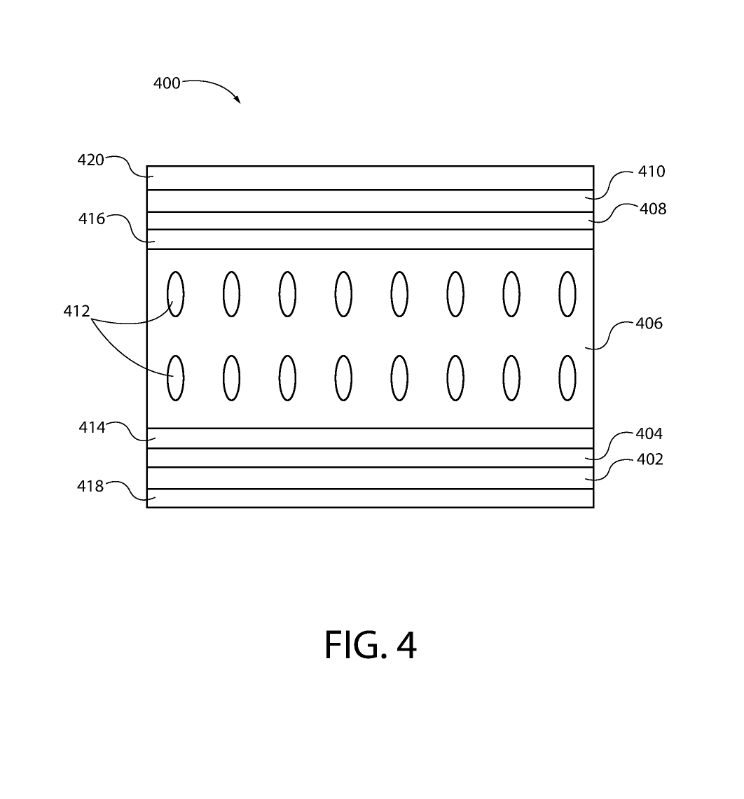

FIG. 4 illustrates the liquid crystal light valve of the display device in accordance with various embodiment of the present invention. The liquid crystal light value 400 includes a first substrate layer 402, a first conductive layer positioned on the first substrate layer 404, a liquid crystal layer 406, a second conductive layer 408, and a second substrate 410 position on the second conductive layer 408, between the second conductive layer 408 and the base panel. Specifically, the second substrate is positioned adjacent the inner surface 204 of base panel 200 in the illustrative embodiment (shown in FIGS. 2A and 2B) and adjacent the protective layer 318 in the alternate embodiment (shown in FIG. 3). The first and second substrate layers 402 and 410 are transparent and may include, for example, material such as glass, plastic, quartz, or the like, which allows the liquid crystal light valve 400 to maintain a transparent state as desired.

The liquid crystal layer 406 is disposed between the first and second conductive layers 404 and 408 and includes a plurality of liquid crystal molecules 412. The liquid crystal light valve 400 is switched from the transparent to the non-transparent state by controlling the rotation of the liquid crystal molecules 412 within the liquid crystal layer 406. In particular, the transparency of the liquid crystal light valve 400 is controlled by adjusting the voltage differential of the driving means (not shown) between the first and second conductive layers 404 and 408 sandwiching the liquid crystal layer 406.

The liquid crystal light valve 400 may also include first and second alignment films 414 and 416, which provide alignment functionality to align the liquid crystal molecules 412 within the liquid crystal layer 406. The liquid crystal light valve 400 may also include first and second polarization layers 418 and 420. It should be clear to those skilled in the art that the alignment directions of the first and second alignment films 414 and 416 and the polarization directions of the first and second polarization layers 418 and 420 can be adjusted as required in order to allow the liquid crystal light valve 400 to be in the transparent state or non-transparent state according to the driving means. It should also be noted that the light valve described in the various embodiment of the invention is for illustrative purposes and the present invention is not limited to the specific light valve arrangement or configuration described herein.

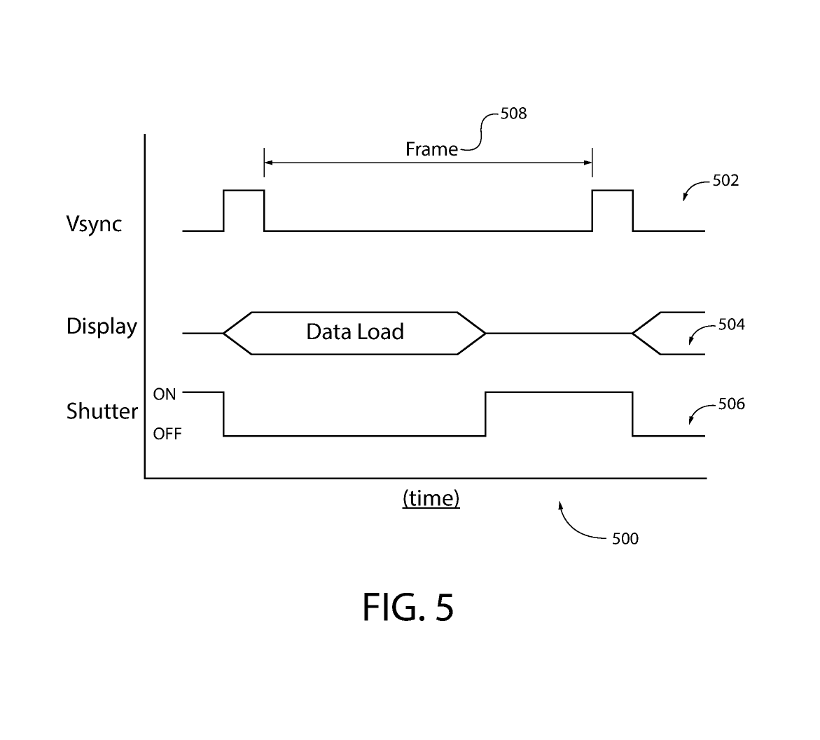

FIG. 5 illustrates a simplified timing diagram 500 of the exemplary operation of the display device implementing global illumination in accordance with the present invention. The shutter has an on-time state (transparent) and an off-time state (non-transparent), which is controlled and set by a synchronizing circuit that is programmed to turn on the shutter for a predetermined amount of time after the display has been fully scanned and loaded. As illustrated, the on-time period occurs after the image data has been loaded into the display using a conventional raster scanned technique, and prior to the start of the next frame.

The timing diagram 500 illustrates the timing of a synchronous signal (Vsync), the timing of video data being loaded into the display device, and the timing of the shutter operation over a time interval 508 (e.g. frame, single frame period, frame time, or 1/60 of a second). Line 502 illustrates the synchronous signal (Vsync). Line 504 illustrates the timing of loading video or image data. Line 506 illustrates the on-time and off-time of the shutter. The time interval 508 is a frame, which includes a first portion video frame and a second portion video frame. The on-time of the shutter occurs during the second portion video frame. The off-time of the shutter occurs during the first portion video frame. In the exemplary implementation, the image data is received by the controller 106 and loaded to the array by a sequential addressing of individual rows, also referred to as scan lines, according to conventional raster-scanned techniques. Once all image data has been loaded for all rows in the array, the shutter is turned on for a pre-determined amount of time (e.g. a fraction of the frame time or fraction of 1/60 of a second). During the on-time state, the shutter is transparent allowing light to pass and image data is not loading. One the shutter is switched to the off-time state, light is no longer allowed to pass therethrough and the image data is loaded into the array in accordance with conventional techniques.

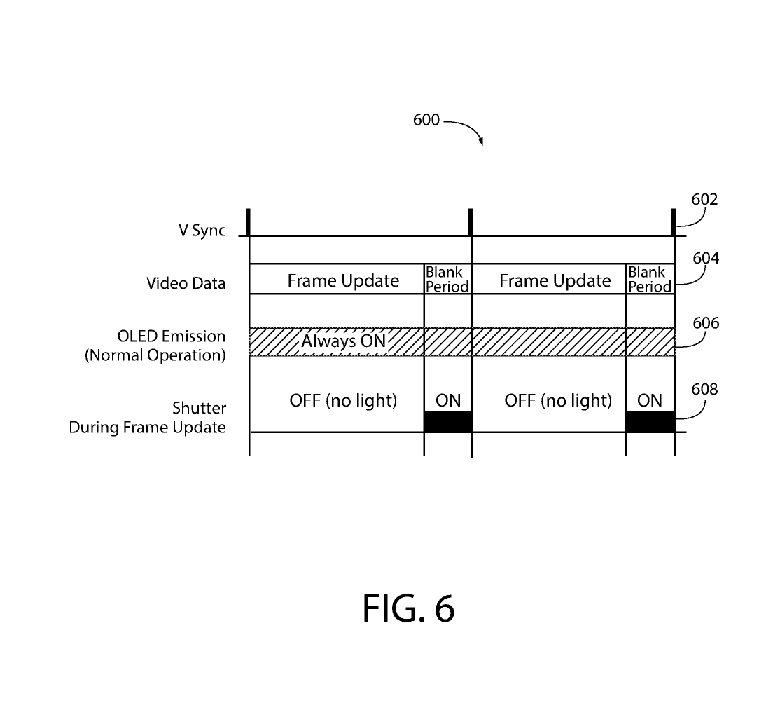

FIG. 6 illustrates a schematic diagram of the timing scheme 600 of the display device implementing global illumination. The timing diagram 600 illustrates line 602 as the timing of a synchronous signal (Vsync), line 604 as video data signal, line 606 as the OLED emission under normal operation, and line 608 as the shutter operation. The image or frame data is loaded into the display in accordance with line 604, while the shutter operation shown by line 608 is in the off-time. Once the frame data is completely loaded the shutter is switched to the on-time according to line 608. During the on-time state of the shutter, the video data signal is blank (i.e. not updating) and light is permitted to pass through the shutter. Once the shutter is switched to the off-time state, light is no longer permitted to pass therethrough and the image data continues loading into the array in accordance with conventional techniques.

It is to be understood that the disclosure describes a few embodiments and that many variations of the invention can easily be devised by those skilled in the art after reading this disclosure and that the scope of the present invention is to be determined by the following claims.

What is claimed is:

1. A method of controlling emission of light in a display device which receives image data from a video source, the display device having a screen and comprising a plurality of pixels each including a light emitting element configured to emit light along a path from the pixel to the screen, the steps comprising:
a) providing a shutter disposed on the display device and operated to block emission of light from all pixels during a first portion video frame;
b) loading image data into each one of the plurality of pixels and controlling the light emitting element of each pixel based on the image data received during the first portion video frame; and
c) simultaneously enabling emission of light from each pixel through the shutter during a second portion video frame.

2. The method of claim 1 wherein the light-emitting element comprises an organic light emitting diode.

3. The method of claim 1 wherein the shutter is a mechanical light shutter.

4. The method of claim 1 wherein the shutter is an electro-optical light shutter.

5. The method of claim 4 wherein the electro-optical light shutter is a liquid crystal light valve.

6. The method of claim 5 wherein the liquid crystal light valve is a ferroelectric liquid crystal light valve.

7. The method of claim 1 wherein the shutter includes an off-time state during the first portion video frame and an on-time state during the second portion video frame.

8. The method of claim 7 wherein the off-time state of the shutter is non-transparent or closed.

9. The method of claim 7 wherein the on-time state of the shutter is transparent or open.

10. The method of claim 1 wherein the display is a microdisplay.

11. The method of claim 1 wherein the display is active matrix or passive matrix.

12. The method of claim 1 wherein the image data is loaded into the pixels in raster scan order.

13. The method of claim 1 further comprising a frame including the first portion video frame and the second portion video frame.

14. The method of claim 13 wherein the frame is 1/60 of a second.

15. A method of operating a display system in communication with a video source for receiving image data, comprising:
providing a display device having a screen for displaying image data, the display device having a plurality of pixels each including a light-emitting diode;
emitting light from each light emitting diode along a path from the pixel to the screen;
providing a shutter coupled to the display device having an on-time state and an off-time state, wherein the on-time state allowing transmission of light to pass therethrough and the off-time state blocking transmission of light from passing therethrough;
loading image data into the plurality of pixels in raster scan order until a full image is loaded;
switching the shutter from off-time state to the on-time state to simultaneously allow emission of light from each pixel to pass through the shutter; and
displaying the full image on the screen by simultaneously displaying image data for each of the plurality of pixels.

16. The method of claim 15 wherein the plurality of pixels comprise active-matrix organic light-emitting diodes.

17. The method of claim 15 wherein the shutter is a mechanical light shutter.

18. The method of claim 15 wherein the shutter is an electro-optical light shutter.

19. The method of claim 18 wherein the electro-optical light shutter is a liquid crystal light valve.

20. The method of claim 19 wherein the liquid crystal light valve is a ferroelectric liquid crystal light valve.
